(19) United States
(12) Patent Application Publication
(10) Pub. No.: US 2024/0204077 A1
(43) Pub. Date: Jun. 20, 2024

(54) FAST SWITCHING TRANSISTORS

(71) Applicant: George Mason University, Fairfax, VA (US)

(72) Inventors: Parameswari Raju, Austin, TX (US); Qiliang Li, Fairfax, VA (US)

(21) Appl. No.: 18/541,831

(22) Filed: Dec. 15, 2023

Related U.S. Application Data
(60) Provisional application No. 63/432,825, filed on Dec. 15, 2022.

(51) Int. Cl. H01L 29/49; H01L 29/24; H01L 29/76; H01L 29/786

(52) U.S. Cl. CPC H01L 29/4908; H01L 29/24; H01L 29/7606; H01L 29/78696

(57) ABSTRACT

A transistor includes a gate, a channel, a gate dielectric at least partially disposed between the gate and the channel, and at least one two-dimensional (2D) layer of a heterostructure disposed within the gate dielectric and spaced from both the gate and the channel. The channel and at least one 2D layer are configured to define a negative quantum capacitance such that a subthreshold slope of the transistor is less than 60 mV/dec.

### CROSS-REFERENCE TO RELATED APPLICATIONS

This application claims the benefit of U.S. Provisional Patent Application No. 63/432,825, filed on Dec. 15, 2022 and titled “FAST SWITCHING TRANSISTORS,” the entire contents of which are hereby incorporated herein by reference.

### FIELD

The present disclosure relates to fast switching transistors and, more specifically, to fast switching transistors, e.g., field effect transistors (FETs) or metal-oxide semiconductor field effect transistors (MOSFETs).

### BACKGROUND

Down-scaling of the supply voltage is of major interest in transistor innovation for mobile, Internet of Things (IoT), and other electronic devices. One manner of reducing the required supply voltage of a transistor is by lowering the subthreshold slope of the transistor, also referred to as a steep subthreshold slope.

Various physical phenomena such as band to band tunneling, negative capacitance, and impact ionization have been proposed to achieve subthreshold slopes less than the Boltzmann limit (60 mV/dec). More recently, innovative research for achieving steep subthreshold slope transistors has focused on using the negative capacitance effect, since it can be incorporated into conventional transistor device structures by the addition of a ferroelectric material layer in the gate stack. However, one big challenge with these devices is that the ferroelectric materials suffer from the hysteresis effect.

Accordingly, achieving steep subthreshold slopes (e.g., less than the Boltzmann limit of 60 mV/dec) without compromising device performance remains a challenge.

### SUMMARY

The terms “about,” “substantially,” and the like, as utilized herein, are meant to account for manufacturing, material, environmental, use, and/or measurement tolerances and variations, as well as other tolerances and/or variations, and in any event may encompass differences of up to 10%. Further, to the extent consistent, any of the aspects described herein may be used in conjunction with any or all of the other aspects described herein. In particular, the present disclosure explicitly contemplates the use of the various materials and numbers of layers detailed herein in any combination thereof.

A transistor provided in accordance with the present disclosure includes a gate, a channel, a gate dielectric at least partially disposed between the gate and the channel, and at least one two-dimensional (2D) layer of a heterostructure disposed within the gate dielectric and spaced from both the gate and the channel. The channel and the at least one 2D layer may be configured to define a negative quantum capacitance such that a subthreshold slope of the transistor is less than 60 mV/dec.

In aspects of the present disclosure, the at least one 2D layer of the heterostructure is a single 2D layer. The single 2D layer may be a single atomic monolayer or a single monolayer of a material, such as a Graphene layer or a single layer of Molybdenume Disulfied (MoS₂).

In aspects of the present disclosure, the at least one 2D layer of the heterostructure is graphene, germanene, or a topological insulator. Where the at least one 2D layer is a topological insulator, the topological insulator may be Ge, Gel, T′-WTe₂, Bi₂Te₃, LaAlO₃/SrTiO₃, T′-MoTe₂, or TaIrTe₄.

In aspects of the present disclosure, the channel includes at least one 2D layer of material. In aspects, the channel includes a plurality of 2D layers.

In aspects of the present disclosure, the at least one 2D layer of material of the channel is: MoS₂, WSe₂, WTe₂, or In₂Se₃.

In aspects of the present disclosure, the channel is formed from three two-dimensional (2D) layers of MoS₂ and the insert is formed from one layer of Graphene.

In aspects of the present disclosure, the plurality of 2D layers of the channel includes at least one layer of a first material and at least one layer of a second, different material. In such aspects, the at least one first material may be one of: MoS₂, WSe₂, WTe₂, or In₂Se₃, and/or the at least one second material may be one of: WSe₂, WTe₂, or In₂Se₃.

In aspects of the present disclosure, a distance between the channel and the at least one 2D layer of the heterostructure is about 9.2 nm. In aspects of the present disclosure, a distance between the channel and the at least one 2D layer of the heterostructure is about 9.2 nm plus or minus one monolayer of dielectric material. In aspects of the present disclosure, a distance between the channel and the at least one 2D layer of the heterostructure is about 9.2 nm plus or minus two monolayers of the dielectric material.

In aspects of the present disclosure, the channel is maintained under tensile strain in a direction perpendicular to the 2D layers to facilitate lowering the subthreshold slope.

In aspects of the present disclosure, the channel is substantially unstrained in an in-plane direction of the 2D layer to inhibit increase of the subthreshold slope.

In aspects of the present disclosure, the transistor further includes a substrate having the gate embedded therein.

Another transistor provided in accordance with the present disclosure includes a stack including a gate, a gate dielectric, and a channel. The channel is formed from a plurality of two-dimensional (2D) layers of material. The transistor further includes an insert including at least one 2D layer of material. The insert is disposed within the gate dielectric between the gate and the channel. The stack may be configured to define a negative quantum capacitance, such that a subthreshold slope of the transistor is less than 60 mV/dec.

In aspects of the present disclosure, the at least one 2D layer of material of the insert is graphene, germanene, or a topological insulator. Where the at least one 2D layer of material of the insert is a topological insulator, the topological insulator may be Ge, GeI, T′-WTe₂, Bi₂Te₃, LaALO₃/SrTiO₃, T′-MoTe₂, or TaIrTe₄.

In aspects of the present disclosure, at least one layer of the plurality of 2D layers of material of the channel is: MoS₂, WSe₂, WTe₂, or In₂Se₃.

In aspects of the present disclosure, the plurality of 2D layers of material of the channel includes at least one layer of a first material and at least one layer of a second, different material.

In aspects of the present disclosure, the stack is maintained under tensile strain in a direction perpendicular to the stack to facilitate lowering the subthreshold slope.

In aspects of the present disclosure, the stack further includes a substrate having the gate embedded therein.

Another transistor provided in accordance with aspects of the present disclosure includes a stack including a gate, a gate dielectric, and a channel. The channel is formed from three two-dimensional (2D) layers of MoS₂. The transistor further includes an insert formed from one single 2D layer of T′WTe₂. The insert is disposed within the gate dielectric between the gate and the channel.

### BRIEF DESCRIPTION OF DRAWINGS

The above and other aspects and features of the present disclosure will become more apparent in view of the following detailed description when taken in conjunction with the accompanying drawings wherein like reference numerals identify similar or identical elements.

FIG. 1 is cross-sectional view of a transistor in accordance with aspects of the present disclosure;

FIG. 2 is a simulation model illustrating a portion of the transistor of FIG. 1 including the gate dielectric (including the insert material therein) and the channel of the transistor;

FIG. 3 is cross-sectional view of another transistor in accordance with aspects of the present disclosure;

FIG. 4 is a simulation model illustrating a portion of the transistor of FIG. 3 including the gate dielectric (including the insert material therein) and the channel of the transistor;

FIG. 5 is a chart indicating the subthreshold slopes for various different number of channel layers, channel material, and single-layer inserted material combinations in accordance with aspects of the present disclosure, wherein the subthreshold slopes were obtained via simulation;

FIG. 6 is a chart indicating the subthreshold slopes for various different number of channel layers and number of inserted layers combinations using an MoS₂ channel and with graphene as the inserted material in accordance with aspects of the present disclosure, wherein the subthreshold slopes were obtained via simulation;

FIG. 7 is a graph illustrating the effects of biaxial compression strain in the x-y plane and biaxial tensile strain in the x-y plane on the minimum subthreshold slope in accordance with the present disclosure, wherein the results were obtained via simulation;

FIG. 8 is a graph illustrating the effects of compression strain along the z-axis and tensile strain along the z-axis on the minimum subthreshold slope in accordance with the present disclosure, wherein the results were obtained via simulation;

FIG. 9 is a graph illustrating the effects of different percentages of nitrogen doping of a graphene inserted layer on the minimum subthreshold slope in accordance with the present disclosure, wherein the results were obtained via simulation;

FIG. 10 is a cross-sectional transmission electron microscope (TEM) image of a transistor including an MoS₂ channel, an Al₂O₃ gate dielectric with encapsulated SL-graphene insert 2D layer, and an embedded metal gate in accordance with the present disclosure;

FIG. 11A is a graph providing an I_{D}-V_{G} curve illustrating transfer characteristics of the transistor of FIG. 10, wherein the results were obtained experimentally;

FIG. 11B is a graph illustrating subthreshold slope versus V_{G} of the transistor of FIG. 10 extracted from the I_{D}-V_{G} curve of FIG. 11A, wherein the results were obtained experimentally; and

FIG. 12 is a graph showing the subthreshold slopes of six different transistor configurations in accordance with the present disclosure, wherein the subthreshold slopes were obtained via simulation.

### DETAILED DESCRIPTION

Subthreshold slope (with units of mV/dec, as utilized herein) is an important parameter in evaluating the performance of transistors. In general, transistors with smaller (steeper) subthreshold slopes switch faster and consume less energy. The use of quantum coupled heterostructures incorporated into transistors in accordance with the present disclosure may enable steep subthreshold slopes less than the 60 mV/dec Boltzmann limit of minimum subthreshold slope, thus enabling faster switching and less power consumption without compromising transistor performance, e.g., maintaining hysteresis at or below about 10 mV. More specifically, it has been found that quantum coupling heterostructures incorporated into a transistor play an important role in achieving a steep subthreshold slope. In aspects, quantum coupling may be provided by achieving, using the quantum coupling heterostructures, negative quantum capacitance. Tuning the dimensionality of the quantum coupling heterostructures, e.g., as two-dimensional (2D) heterostructures of one or more layers (wherein each layer is a 2D structure), also facilitates achieving a steep subthreshold slope. Other factors that have been found to impact the subthreshold slope include channel thickness, inserted gate thickness, gate dielectric thickness, strain in the gate/channel stack, and doping of the inserted layer(s). These and other aspects and features of the present disclosure are detailed below.

Subthreshold slope of a transistor, as utilized herein and generally accepted in the art, denotes the gate voltage increment required to change the drain current of the transistor by one order of magnitude (decade or dec) and is calculated from the expression:

$$S S = ln ( 10 ) \frac{K T}{q} \frac{d {V}_{G}}{d {ϕ}_{s}} \qquad Equation ( 1 )$$

where SS is the subthreshold slope, V_{G} is the gate voltage, ϕₛ is the surface potential of the channel, and KT/q is the thermal voltage. Further, for composite gates, V_{G} is the voltage of the gate closest to the channel, which may be the inserted 2D material. The channel surface potential as function of gate voltage may be provided by the following expressions:

$$\frac{d {V}_{G}}{d {ϕ}_{s}} = 1 + \frac{{C}_{t o t a l}}{{C}_{OX}} \qquad Equation ( 2 )$$

$$\frac{1}{{C}_{t o t a l}} = \frac{1}{{C}_{S}} + \frac{1}{{C}_{q}} \qquad Equation ( 3 )$$

where Cₜₒₜₐₗ is the parallel combination of the substrate capacitance C_{S} and the quantum capacitance C_{q} of the inserted layer, and C_{OX} is the capacitance of the gate dielectric. C_{q} results from the electron-electron interactions, accounting for both the kinetic and the exchange correlation energies. Further, the quantum capacitance, C_{q}, can be expressed as:

$${C}_{q} = \frac{d Q}{d {ϕ}_{s}} = \frac{{e}^{2}}{4 K T} {\int }_{- ∞}^{∞} D ( E ) {sech}^{2} [ \frac{E - {ϕ}_{S}}{2 K T} ] d E \qquad Equation ( 4 )$$

where Q is the insertion layer charge density, e is the electron charge, KT is the thermal energy, and D(E) is the DOS at energy E.

The transistors in accordance with the present disclosure may incorporate quantum coupled heterostructures and may achieve a negative quantum capacitance, C_{q}, and, thus, a negative Cₜₒₜₐₗ. As a result, subthreshold slopes less than 60 mV/dec may be achieved. The present disclosure describes various transistor configurations which may include quantum coupled heterostructures (and thus may provide negative quantum capacitance, C_{q}), and which may thereby enable subthreshold slopes less than 60 mV/dec.

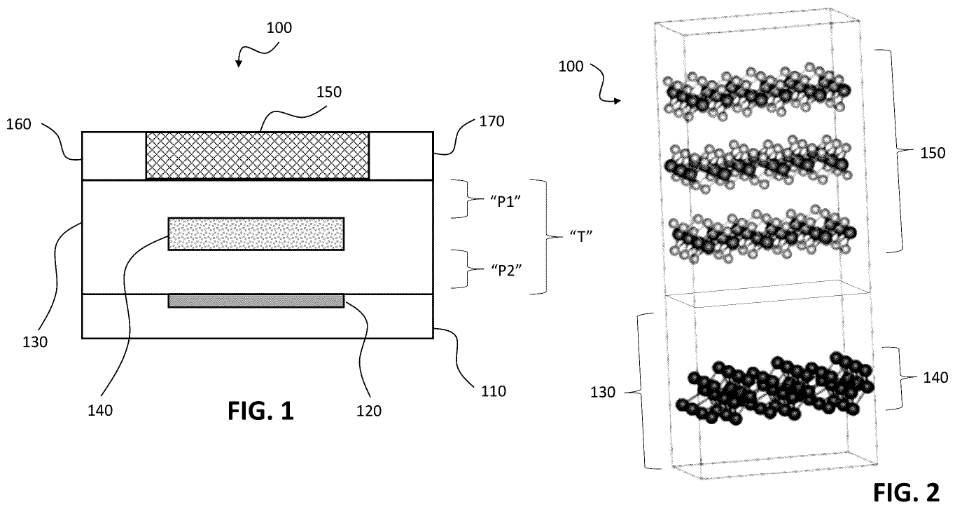

Turning to FIGS. 1 and 2, an exemplary transistor in accordance with the present disclosure is shown generally identified by reference numeral 100. The transistor 100 includes a substrate 110, a gate 120 which may be disposed on or may be embedded within the substrate 110, a gate dielectric 130 stacked on the substrate 110, an insertion layer heterostructure 140 (e.g., of one or more two dimensional layers) inserted into the gate dielectric 130, a channel 150 stacked on the gate dielectric 130, and a source and drain 160, 170 stacked on the gate dielectric 130 and connected via the channel 150. The insertion layer heterostructure may be a quantum coupled heterostructure. However, other suitable configurations of the transistor 100 are also contemplated without departing from the aspects and features of the present disclosure.

The substrate 110 may be, for example, an SiO₂/Si wafer. The gate 120 may be a metal gate and may be, for example, a Ti/Pt gate. In aspects, a Ti/Pt gate 120 is patterned on a 300 nm SiO₂/Si substrate 110 by photolithography, after which reactive ion etching is applied to remove a 50 nm thickness of SiO₂ using CHF₃. In aspects, the gate 120 is embedded and formed by deposition and lift-off of a 5 nm/45 nm Ti/Pt film. However, other suitable substrates, gates, and/or fabrication methods thereof are also contemplated.

The gate dielectric 130 may be aluminum oxide (Al₂O₃) having a plurality of layers (e.g., 2D layers) to achieve an appropriate thickness. As noted above, it has been found that gate dielectric thickness “T” impacts the subthreshold slope of the transistor 100. More specifically, as the spacing between the channel 150 and the inserted quantum coupled heterostructure 140 increases (e.g., due to the thickness of the gate dielectric 130 therebetween), the channel controllability of the gate may decrease and the subthreshold slope may increase due to the inverse relationship between gate capacitance and dielectric thickness “T.” However, on the other hand, increasing the thickness “T” of the gate dielectric 130 helps prevent direct tunneling of electrons and exhibits hysteresis-free characteristics. In aspects, the overall thickness “T” of the gate dielectric 130 is about 17.6 nm. In additional or alternative aspects, the distance between the quantum coupled heterostructure 140 and the channel 150, defined by a first portion “P1” of the thickness “T” of the gate dielectric 130, is about 9.2 nm. In aspects, a second portion “P2” of the thickness “T,” defined between the quantum coupled heterostructure 140 and the gate 120 may be about 8.4 nm. In aspects, atomic layer deposition (ALD) is utilized to deposit the gate dielectric 130 onto the substrate 110 in layer-by-layer fashion until the target thickness is achieved. Other configurations and/or fabrication methods are also contemplated. In aspects, the first portion “P1” thickness may be about 9.2 nm plus one dielectric atomic monolayer. In aspects, the first portion “P1” thickness may be about 9.2 nm minus one dielectric atomic monolayer. In aspects, the first portion “P1” thickness may be about 9.2 nm plus two dielectric atomic monolayers. In aspects, the first portion “P1” thickness may be about 9.2 nm minus two dielectric atomic monolayers. In aspects, the second portion “P2” thickness may be about 8.4 nm plus one dielectric atomic monolayer. In aspects, the second portion “P2” thickness may be about 8.4 nm minus one dielectric atomic monolayer. In aspects, the second portion “P2” thickness may be about 8.4 nm plus two dielectric atomic monolayers. In aspects, the second portion “P2” thickness may be about 8.4 nm minus two dielectric atomic monolayers.

Continuing with reference to FIGS. 1 and 2, the insertion layer heterostructure 140 (of one or more 2D layers), as noted above, may enable achievement of a negative quantum capacitance, and may allow for a subthreshold slope less than 60 mV/dec. In aspects, because it has been found that the thickness of the insertion layer heterostructure 140 impacts the subthreshold slope, the heterostructure 140 may be a single layer. In other aspects, multiple 2D layers of the heterostructure 140 are provided. In aspects, the heterostructure 140 is graphene, germanene, or a topological insulator (including, for example and without limitation, Ge, GeI, T′-WTe₂, Bi₂Te₃, LaAlO₃/SrTiO₃, T′-MoTe₂, and TaIrTe₄). The thickness of the 2D heterostructure 140 depends upon the particular heterostructure utilized and the number of 2D layers. In aspects, the thickness is about 0.7 nm. The heterostructure 140 may be inserted into the gate dielectric 130 onto an initial number of layers of the gate dielectric 130 before the remaining layers of the gate dielectric 130 are deposited or otherwise applied. The heterostructure 140 may be inserted using mechanical exfoliation and dry transfer techniques, although other methods are also contemplated. In aspects, the heterostructure 140 does not extend beyond the gate 120 (e.g., in length or width dimensions from the stack oriented in FIG. 1) to avoid parasitic (overlap) capacitance.

The channel 150 may include one or more layers of 2D material, although other configurations are also contemplated. The thickness of the channel 150, defined at least in part by the number of 2D layers, has been found to impact the subthreshold slope. More specifically, it has been found that, for some transistor structures and/or in some circumstances, increasing the number of 2D layers (and, thus, the thickness), initially increases the surface potential; however, above a certain thickness, the surface potential decreases again. Accordingly, in aspects, the number of 2D layers may be two layers, three layers, or four layers. However, a single layer or more than four layers are also contemplated in some configurations.

The channel 150 may be made from one or more 2D layers of MoS₂, WSe₂, WTe₂, In₂Se₃, and/or or any other suitable material(s) stacked on each other. In aspects, the channel 150 is disposed relative to the heterostructure 140 in a vertical stack such that any lattice mismatch between the channel 150 and the heterostructure 140 and/or the layers of either or both of the channel 150 and the heterostructure 140 is equal to or less than about 5%. It has been found that, for some transistor structures, utilizing the same material for the channel 150 and heterostructure 140 may not be advantageous for achieving negative quantum capacitance and, thus, a steep subthreshold slope. Accordingly, in aspects, at least some of the materials of the channel 150 and heterostructure 140 are different.

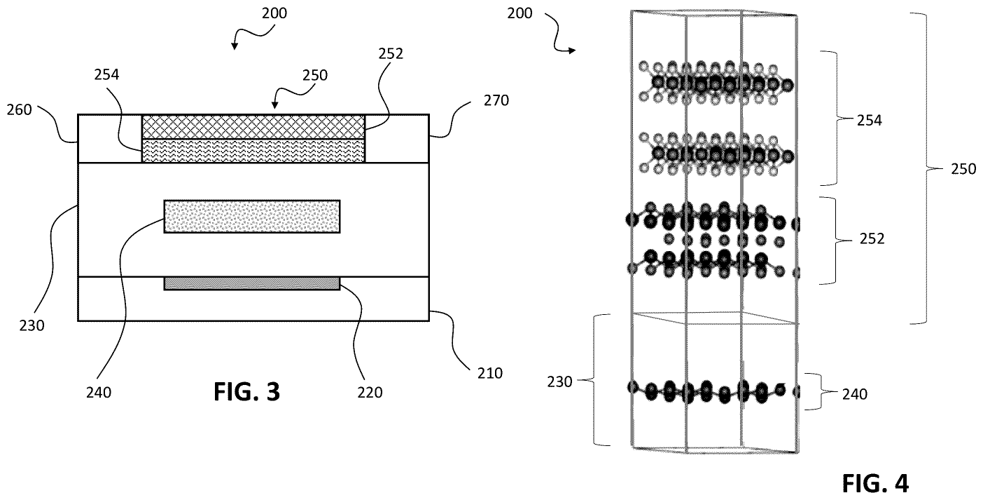

In aspects where the channel 150 includes two or more 2D layers, the 2D layers may be of the same material or of different materials. Referring momentarily to FIGS. 3 and 4, another transistor 200 in accordance with the present disclosure is shown wherein, in aspects, the channel 250 includes one or more 2D layers 252 of a first material and one or more 2D layers 254 of a second, different material. The first layers 252 may be, for example, In₂Se₃, and the second layers 254 may be, for example, MoS₂, although any other suitable materials for the first and second layers 252, 254, such as those noted above or any other suitable materials, are also contemplated. In aspects, plural first layers 252 and/or plural second layers 254 are provided. Transistor 200 may further include a substrate 210, a gate 220, a gate dielectric 230, an insertion layer heterostructure 240 (which may be quantum coupled), a source 260, and a drain 270 and may otherwise be configured according to any of the aspects detailed herein with respect to transistor 100 (FIG. 1).

Referring again to FIG. 1, the source and drain 160, 170 may be any suitable material formed in any suitable manner. For example, in aspects, the source and drain 160, 170 are Ti/Au and, in aspects, may be patterned and formed by electron beam lithography and sputtering/lift-off processes. The source 160 is connected to a first end of the channel 150 whereas the drain 170 is connected to a second end of the channel 150.

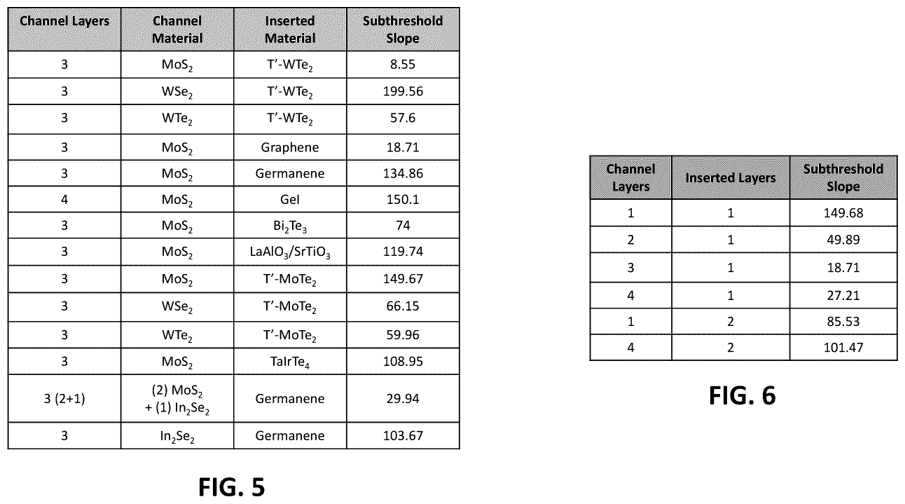

Turning to FIG. 5 and FIG. 6, the tables show transistor configurations and their corresponding estimated subthreshold slopes. Each line of the table in FIG. 5 corresponds to an exemplary embodiment of a transistor 100 including a channel 150 and an inserted layer heterostructure 140, wherein the channel 150 includes the number of 2D layers shown in column one having a 2D layer material as shown in column two, and wherein the inserted heterostructure 140 includes a 2D layer including the material shown in column three. Each line of the table in FIG. 6 corresponds to an exemplary embodiment of a transistor 100 including a channel 150 and an inserted layer heterostructure 140, wherein the channel 150 includes the number of 2D MoS₂ layers shown in column one, and wherein the inserted heterostructure 140 includes the number of 2D Graphene layers shown in column two. The tables of FIGS. 5 and 6, tables show results obtained by simulation in accordance with the present disclosure and illustrate the effects of various different combinations of channel layers, channel layer materials, heterostructure layers, and heterostructure materials on the minimum subthreshold slope of a transistor. FIG. 5, more specifically, illustrates the subthreshold slopes for various different number of channel layers, channel material, and inserted material (of single layer heterostructure) combinations. FIG. 6, more specifically, illustrates the subthreshold slopes for various different number of channel layers and number of inserted layers combinations where the channel material is MoS₂ and the inserted material is graphene.

The results shown in the tables of FIGS. 5 and 6 were obtained by simulation utilizing the density functional theory (DFT) in accordance with the present disclosure. Such simulations have yielded subthreshold slopes of 27.2 mV/dec (utilizing three 2D layers of graphene as the inserted heterostructure and a single 2D layer of MoS₂ as the channel) and as low as 8.6 mV/dec (utilizing three 2D layers of WTe₂ as the inserted heterostructure and a single 2D layer of MoS₂ as the channel). However, the present disclosure is not limited to these exemplary configurations or the results of any of the configurations provided in FIGS. 5 and 6.

Referring to FIG. 12, in conjunction with FIG. 1, subthreshold slopes of several exemplary embodiments of a transistor 100 are shown. The first bar (4M1G) in the graph of FIG. 12 shows the subthreshold slope corresponding to a transistor 100 including a channel 150 having four MoS₂ layers and a heterostructure 140 having one 2D Graphene layer. The second bar (4W1G) in FIG. 12 shows the subthreshold slope corresponding to a transistor 100 including a channel 150 having four WSe₂ layers and a heterostructure 140 having one 2D Graphene layer. The third bar (3M1G) in FIG. 12 shows the subthreshold slope corresponding to a transistor 100 including a channel 150 having three MoS₂ layers and a heterostructure 140 having one 2D Graphene layer. The fourth bar (4M1Ge) in FIG. 12 shows the subthreshold slope corresponding to a transistor 100 including a channel 150 having four MoS₂ layers and a heterostructure 140 having one 2D Germanene layer. The fifth bar (4M1GeI) in FIG. 12 shows the subthreshold slope corresponding to a transistor 100 including a channel 150 having four MoS₂ layers and a heterostructure 140 having one 2D Germanium Iodide layer. The sixth bar (3M1W) in FIG. 12 shows the subthreshold slope corresponding to a transistor 100 including a channel 150 having three MoS₂ layers and a heterostructure 140 having one 2D T′ WTe₂ layer.

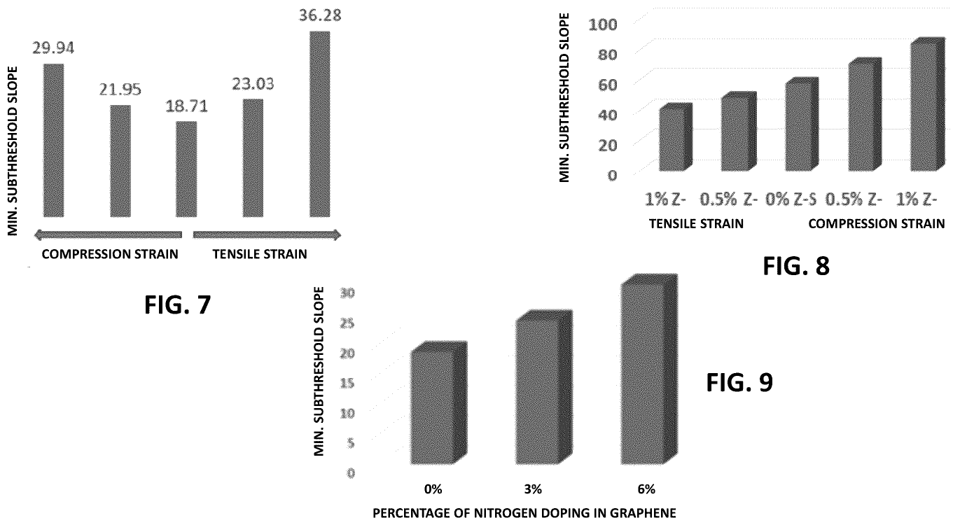

With reference to FIGS. 7 and 8, strain on the transistor and, more specifically, the channel thereof, has been found to impact the subthreshold slope. More specifically, as shown in FIG. 7, in some embodiments, both compression and tensile strain on the channel may increase the minimum attainable subthreshold slope. This was confirmed via simulation, for some embodiments, by applying biaxial compression strain (e.g., in the x-y plane (in-plane or parallel to the transistor layers)) and biaxial tensile strain (e.g., in the x-y plane (in-plane or parallel to the transistor layers)), with the results shown graphically in FIG. 7. With respect to FIG. 8, compression strain (decreasing the interlayer distance in the channel) and tensile strain (increasing the interlayer distance in the channel) in the vertical direction (e.g., along the z-axis, or along an axis perpendicular to the transistor layers) were also applied and the result obtained via simulation. As shown in FIG. 8, in some embodiments, and based upon the above-noted simulation results, while compressive strain increased the minimum subthreshold slope (e.g., from 57.57 to 84.13), the application of tensile strain decreased the minimum subthreshold slope (e.g., from 57.57 to 40.8). Thus, tensile strain applied to the channel may be utilized to decrease subthreshold slope, while other strains, in aspects, are avoided or minimized to prevent resultant increases in subthreshold slope. In aspects, the transistor 100 may include a channel 150 which is under tensile strain in a direction perpendicular to the 2D layers. In aspects, the transistor 100 may include a channel 150 which is under compression strain in a direction perpendicular to the 2D layers (z direction). In aspects, the transistor 100 may include a channel 150 which is under tensile strain in an in-plane direction (x-y direction). In aspects, the transistor 100 may include a channel 150 which is under compression strain in an in-plane direction (x-y direction).

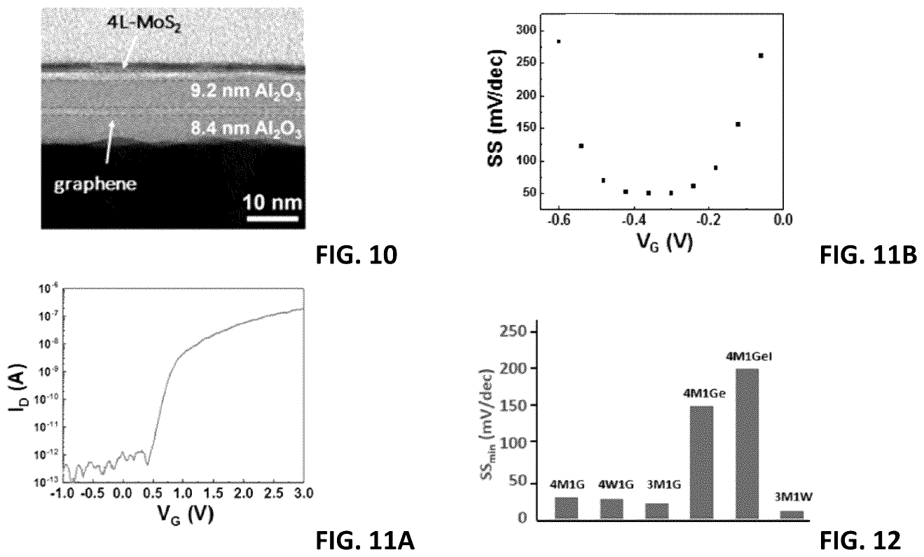

Turning to FIG. 9, it has been found, by theoretical analysis, that the quantum capacitance of graphene (as the inserted 2D material of one or more layers) can be improved by doping or introducing vacancy defects. Simulation results indicating the effect of nitrogen doping of graphene on subthreshold slope are shown in FIG. 9, wherein nitrogen doped graphene at two different concentration levels (3% and 6%) is compared to undoped graphene (0% concentration). As shown in FIG. 9, the results suggest that, in some circumstances and for some embodiments, doping the 2D inserted graphene layer(s) increased the subthreshold slope, e.g., from 18.71 (without doping) to 22.62 (for 3% doping concentration), and to 29.74 (for 6% doping concentration). Thus, in some embodiments, doping may degrade the steepness of the subthreshold slope; however, the effect is relatively minor and still enables subthreshold slopes well below 60 mV/dec. Accordingly, doping and/or vacancy defects may be utilized in some configurations, especially where advantageous for other purposes. In aspects, the transistor 100 may include a heterostructure 140 which is doped with Nitrogen or other dopants. FIG. 10 is a cross-sectional transmission electron microscope (TEM) image of an embodiment of a transistor including an MoS₂ channel, an Al₂O₃ gate dielectric with encapsulated SL-graphene insert 2D layer, and an embedded metal gate. Experimental results obtained using the transistor of FIG. 10 are illustrated in FIGS. 11A and 11B, wherein FIG. 11A provides a graph including an I_{D}-V_{G} curve illustrating transfer characteristics obtained experimentally for the transistor of FIG. 10, and wherein FIG. 11B is a graph illustrating subthreshold slope versus V_{G} for the transistor of FIG. 10, extracted from the I_{D}-V_{G} curve of FIG. 11A and obtained experimentally for the transistor of FIG. 10.

While several aspects of the disclosure have been shown in the drawings, it is not intended that the disclosure be limited thereto, as it is intended that the disclosure be as broad in scope as the art will allow and that the specification be read likewise. Therefore, the above description should not be construed as limiting, but merely as exemplifications of particular configurations. Those skilled in the art will envision other modifications within the scope and spirit of the claims appended hereto.

What is claimed is:

1. A transistor, comprising:
a gate;
a channel;
a gate dielectric at least partially disposed between the gate and the channel; and
at least one two-dimensional (2D) layer of a heterostructure disposed within the gate dielectric and spaced from both the gate and the channel,
wherein the channel and the at least one 2D layer are configured to define a negative quantum capacitance such that a subthreshold slope of the transistor is less than 60 mV/dec.

2. The transistor according to claim 1, wherein the at least one 2D layer is a single 2D layer.

3. The transistor according to claim 1, wherein the at least one 2D layer is graphene, germanene, or a topological insulator.

4. The transistor according to claim 3, wherein the at least one 2D layer is the topological insulator, and wherein the topological insulator is Ge, GeI, T′-WTe₂, Bi₂Te₃, LaALO₃/SrTiO₃, T′-MoTe₂, or TaIrTe₄.

5. The transistor according to claim 1, wherein the channel is formed from three two-dimensional (2D) layers of MoS₂ and the insert is formed from one layer of Graphene.

6. The transistor according to claim 5, wherein the at least one 2D layer of material of the channel is: MoS₂, WSe₂, WTe₂, or In₂Se₃.

7. The transistor according to claim 1, wherein the channel includes a plurality of 2D layers of material.

8. The transistor according to claim 7, wherein the plurality of 2D layers of the channel includes at least one layer of a first material and at least one layer of a second, different material.

9. The transistor according to claim 8, wherein the at least one first material is one of: MoS₂, WSe₂, WTe₂, or In₂Se₃, and wherein the at least one second material is one of: WSe₂, WTe₂, or In₂Se₃.

10. The transistor according to claim 1, wherein a distance between the channel and the at least one 2D layer is about 9.2 nm plus or minus up to two 2D layers of dielectric material.

11. The transistor according to claim 1, wherein the channel is maintained under tensile strain in a direction perpendicular to the at least one 2D layer, the tensile strain facilitating lowering the subthreshold slope.

12. The transistor according to claim 11, wherein the channel is substantially unstrained in an in-plane direction of the at least one 2D layer to inhibit increase of the subthreshold slope.

13. The transistor according to claim 1, further comprising a substrate, wherein the gate is embedded in the substrate.

14. A transistor, comprising:
a stack including a gate, a gate dielectric, and a channel, wherein the channel is formed from a plurality of two-dimensional (2D) layers of material; and
an insert including at least one 2D layer of material, the insert disposed within the gate dielectric between the gate and the channel,
wherein the stack is configured to define a negative quantum capacitance, such that a subthreshold slope of the transistor is less than 60 mV/dec.

15. The transistor according to claim 14, wherein the at least one 2D layer of material of the insert is graphene, germanene, or a topological insulator.

16. The transistor according to claim 14, wherein the at least one 2D layer of material of the insert is the topological insulator, and wherein the topological insulator is Ge, GeI, T′-WTe₂, BizTe₃, LaALO₃/SrTiO₃, T′-MoTe₂, or TaIrTe₄.

17. The transistor according to claim 14, wherein at least one layer of the plurality of 2D layers of material of the channel is: MoS₂, WSe₂, WTe₂, or In₂Se₃.

18. The transistor according to claim 14, wherein the plurality of 2D layers of material of the channel includes at least one layer of a first material and at least one layer of a second, different material.

19. The transistor according to claim 14, wherein the stack is maintained under tensile strain in a direction perpendicular to the stack, the tensile strain facilitating lowering the subthreshold slope.

20. A transistor, comprising:
a stack including a gate, a gate dielectric, and a channel, wherein the channel is formed from three two-dimensional (2D) layers of MoS₂; and
an insert formed from one single 2D layer of T′WTe₂, the insert disposed within the gate dielectric between the gate and the channel.
